(19) United States
(12) Patent Application Publication
(10) Pub. No.: US 2009/0084599 A1
(43) Pub. Date: Apr. 2, 2009

(54) NANO INKS FOR IMPARTING EMI SHIELDING TO WINDOWS

(75) Inventors: Christopher L. Severance, Derry, NH (US); Ronald McBride, Pittsgrove, NJ (US); Matthew Finley, Moorestown, NJ (US)

Correspondence Address: RISSMAN JOBSE HENDRICKS & OLIVERIO, LLP, 100 Cambridge Street, Suite 2101, BOSTON, MA, 02114, US

(73) Assignee: Parker Hannifin Corporation, Cleveland, OH (US)

(21) Appl. No.: 12/241,202

(22) Filed: Sep. 30, 2008

Related U.S. Application Data
(60) Provisional application No. 60/976,905, filed on Oct. 2, 2007.

(51) Int. Cl. H05K 9/00

(52) U.S. Cl. 174/350; 361/818

(57) ABSTRACT

An EMI shielded display window for an electronic device is prepared by coating at least one surface of the window with an optically transparent shielding layer. The shielding layer is a coating or ink containing conductive nanoparticles applied to the window at a thickness of 10 microns or less. The coating can be optionally plated with a layer of copper, silver or nickel for improved performance.

### CROSS-REFERENCE TO RELATED APPLICATIONS

This application claims the benefit of U.S. Provisional Application No. 60/976,905, filed on Oct. 2, 2007, the disclosure of which is incorporated herein by reference.

### BACKGROUND OF THE INVENTION

The present invention relates to nanoparticles used as conductive fillers for electromagnetic interference (EMI) or radio interference (RFI) shielding coatings and inks. The optically transparent coatings and inks of this invention are applied to an interior or internal surface of a window of an electronic device, such as a screen for a computer monitor or display panel.

As is known in the art, EMI energy is radiated or conducted energy that adversely affects the performance of an electronic circuit. EMI and/or RFI may be eliminated or reduced by the use of shielded enclosures and the use of appropriate shielding materials.

The operation of electronic equipment, such as televisions, radios, computers, medical instruments, business machines, communication equipment, and the like, is typically accompanied by the generation of radio frequency and/or electromagnetic radiation within the electronic circuits of an electronic system. The increasing operating frequency in commercial electronic enclosures, such as computers and automotive electronic modules, results in an elevated level of high frequency electromagnetic interference (EMI). The decrease in size of handheld electronic devices, such as cellular phone handsets, has exacerbated the problem. If not properly shielded, such radiation can cause considerable interference with unrelated equipment. Accordingly, it is necessary to effectively shield and ground all sources of radio frequency and electromagnetic radiation within the electronic system.

Typical EMI protective devices include conductive coatings, EMI shielding gaskets, conductive films, and metalized fabrics, screens and meshes. These devices are deployed to block the transmission of unwanted EMI energy into and out of electronic equipment. Windows containing fine wire mesh and conductive transparent films have been typically used to shield display panels, including displays for electronic devices. Such devices are described in U.S. Pat. Nos. 4,910,090 and 5,489,489, as well as EP 810452, the respective disclosures of which are incorporated by reference herein in their entirety.

Transparent EMI shielding films employing polymers, such as PET, and conductive particles, such as ITO (indium tin oxide), silver and conductive oxides, are available commercially from various suppliers. An example of this type of commercial film is the AgF8 film sold by Parker Hannifin Corporation (Chomerics Division). AgF8 is a multi-layer conductive, silver-oxide based polyester film which has optical transparency and high electrical conductivity. These films, typically on the order of 175 microns in thickness, are used to shield electronic equipment, such as electronic displays and membrane switch panels, from EMI/RFI radiation.

Notwithstanding the favorable shielding properties of many of the film products currently on the market, these products have generally proven to be too fragile to handle and lack durability when installed. The films have a tendency to become contaminated over time and loose shielding effectiveness. Moreover, current shielding technology for windows frequently forces the user to choose between optical performance and shielding effectiveness.

The use of electrically conductive inks for static charge dissipation and EMI shielding has also been attempted for various applications.

U.S. Pat. No. 5,137,542 describes abrasive articles having a conductive ink printed on the back and/or front surfaces of the articles in repeating or non-repeating patterns for static dissipation. The conductive ink is described as a liquid dispersion containing a solvent, a resin or polymer, and an electrically conductive pigment. The ink can be cured to a final thickness of less than about 4 microns.

U.S. Pat. No.6,537,459 is directed to deformable, electrically conductive inks applied to substrates in defined patterns. The electrically conductive inks of the reference are dispersions of metal (copper, nickel, silver, etc.) or carbon particles and suitable resins in organic solvents. The conductive particles are shaped like plates or flakes having dimensions of between about 1 micron and 0.1 micron. The ink can be applied to a molded part in the form of a pattern which, when dried, can be elongated or deformed while maintaining electrical conductivity. This characteristic is said to provide suitability for EMI shielding applications.

Notwithstanding the existing products and proposed solutions known in the art, there is a perceived need for an improved EMI shielding coating which is optically transparent and suitable for coating windows used in electronic equipment. The improved coated window should be capable of providing at least comparable shielding effectiveness to existing products, without suffering from the disadvantages noted previously.

### SUMMARY OF THE INVENTION

The present invention provides an EMI shielded window for use in electronic devices and displays. The shielded window comprises a substrate of a plastic or glass having a coating thereon of a transparent shielding layer comprising a polymeric coating or ink containing conductive or EMI absorptive nanoparticles. Optionally, a layer of metal can be plated onto the conductive coating for additional shielding protection. The conductive coating of the invention can be applied to the inner or internal surface of the window, i.e. the surface of the window facing the interior of the electronic enclosure, or the coating can be applied to an intermediate surface formed by sandwiching adjacent layers of plastic or glass together.

The window is typically formed from a glass or plastic material wherein the plastic can be an acrylic, a polyurethane, an epoxy, a silicone and copolymers and blends thereof. The window can be part of an enclosure for electronic components and acts as the visual display for information and data, video or graphical. The window can also be a composite structure formed by sandwiching adjacent panels of glass or plastic together.

The nanoparticles of the invention are preferably prepared from EMI conductive and absorptive materials, provided that such materials have both optical clarity and shielding properties with respect to the coated window. These materials include, by way of illustration, silver, gold, Monel, copper, steel, nickel, tin, ITO, and combinations thereof. The nanoparticles can be of various shapes and sizes, provided that the maximum dimension of such particles is less than about 100 nm, and preferably less than about 20 nm.

The nanoparticles are incorporated in a suitable polymer and solvent to form the coating or ink. The polymer can be any of a number of materials suitable for preparing coatings, such as acrylics, polyurethanes, epoxies, silicones, copolymers, and blends thereof, polyvinyl acetate, natural gums and resins, and the like. An ink can be prepared by using an aqueous medium. The amount of nanoparticles present in the coating or ink applied to the window is typically from about 20% to about 80% by weight on a dry basis.

The coating or ink is applied to a surface of the window, preferably the outer surface of the window, to form a transparent shielding layer. The thickness of the coating or ink applied to the window depends on the transparency and the degree of shielding desired. In general, the coating or ink layer advantageously has a thickness of less than about 10 microns. Thicker coatings will generally produce more shielding but at the expense of less transparency. Curing or drying of the coating or ink applied to the window will depend on the curing conditions of the polymer and the type of solvent used, i.e. organic or aqueous, for instance. Curing will generally occur at elevated temperatures, i.e. greater than 50° C. or higher, although room temperature curing (evaporation) can be used in some applications.

### BRIEF DESCRIPTION OF THE DRAWINGS

FIG. 1 is a perspective view of a window coated with a patterned conductive ink providing EMI shielding according to the invention;

FIG. 2 is a cross-sectional view of the window of FIG. 1;

FIG. 3 is an alternative embodiment of the window of FIG. 1; and

FIG. 4 is a perspective view of a computer monitor incorporating a shielded window according to the invention.

### DESCRIPTION OF THE PREFERRED EMBODIMENTS

The present invention is directed to windows for electronic displays having EMI shielding properties and optical clarity. The windows of the invention are coated with a coating or ink layer containing conductive nanoparticles. The nanoparticles of the invention are selected on the basis of optical transparency and EMI shielding characteristics.

EMI/RFI shielding effectiveness and optically clarity are provided by coating the window substrate with a polymer or ink containing conductive nanoparticles. The window is coated on the side facing the electronic enclosure, and the coated layer is optionally sandwiched between two substrates. This approach provides an effective shielding solution without compromising the functionality of the window in terms of its optical performance. It has been found that the use of conductive nanoparticles in the coating or ink permits the use of extremely thin coatings which have at least equivalent shielding performance characteristics as compared to conventional coatings of substantially greater thicknesses and attachable EMI shielding screen members designed to cover the window. For example, a coating of about 10 microns according to the present invention has been found to be the equivalent of a conventional coating requiring an order or magnitude greater thickness in terms of shielding effectiveness, while also having superior optical performance, i.e. optical clarity and transparency.

Optionally, the coated window can be plated with a metal layer using, for instance, electrolytic or electroless plating techniques. The plated layer adheres to the coating and provides additional shielding protection to the window. The plated metal can be, for instance, copper, silver or nickel, and the plating layer can advantageously be less than 10 microns in thickness. The plated layer can be “blackened” after it has been applied to the coating using a sulfide bath. “Blackening” prevents unwanted light reflection and enhances the overall optical and visual effects of the window.

The performance of the shielded window can be measured in terms of both its electrical and optical performance. Optical performance can be defined in terms of optical transparency of the window. Accordingly, by “transparent” or “transparency” is meant, in the context of the invention, that the coated window transmits an amount of light in the visible spectrum of at least about 20% of the original incident light, measured along the normal axis of the window. The unshielded substrate is a glass or plastic element which can be tinted or clear. The window is “clear” when there is an absence of visibly noticeable distortion, haze or flaws as detected by the naked eye at a distance of from about 0.5 to 1 meters from the window. The window can be substantially planar or non-planar, meaning that the surface of the window can be curved (convex, concave, or a combination thereof) or substantially flat.

The electrical performance of the shielded window can be measured by the surface resistivity in ohm/square. A low resistivity is desired as this means that the surface conductivity is high. EMI shielding performance is measured in decibels over a range of frequencies ranging from 20 MHz to 18 GHz, wherein a constant decibel level over this range is preferred. For most applications, an EMI shielding effectiveness of at least about 10 dB, and usually at least about 20 dB, and preferably at least about 60 dB or higher, over a frequency range of from about 10 MHz to 10 GHz, is considered particularly desirable.

A conductive coating or ink layer is applied to all or part of the surface of the window to achieve the EMI shielding and optical effects desired for a particular application. Suitable application techniques are known in the art and include any number of coating, printing and spray techniques, such as, by way of example, ink jet printing, screen printing, gravure printing, flexographic printing, lithographic printing, pad printing, transfer coating and spray painting. The coating of the invention is advantageously applied in a selected pattern at a thickness of less than about 10 microns. A suitable printing pattern, by way of example, is a square grid pattern with printed line widths of from about 30 microns to about 100 microns, and line spacings of from about 300 microns to about 900 mircons.

The conductive coating or ink comprises a polymer and conductive nanoparticles. The thickness of the coating and the loading of the nanoparticles will define the performance. The performance also depends on the loading of the conductive coating, with a higher loading and thicker coating providing superior shielding performance, but at the expense of optical transparency. Typically, the filler proportion of the coating is generally between about 10-80% by volume or 50-90% by weight, based on the total volume or weight, as the case may be, although it is known that comparable EMI shielding effectiveness may be achieved at lower conductivity levels through the use of an EMI absorptive or “lossy” filler.

As used herein, the term “nanoparticle” or “conductive nanoparticle” is intended to define a conductive particle, of regular or irregular shape, having at least one dimension of less than about 100 nanometers (nm), preferably having all dimensions of less than about 100 nm, and most preferably having at least one dimension or all dimensions of less than about 20 nm. Representative nanoparticle shapes include spheres, spheroids, needles, flakes, platelets, fibers, tubes, etc.

The conductive nanoparticles of the invention can be fabricated from conductive or EMI absorptive materials. Operable conductive materials include silver, gold, Monel, copper, steel, nickel, tin and ITO (indium/tin oxide), or any combination thereof. Silver is the preferred material. Operable EMI absorptive materials include ferrite among others.

The nanoparticles are mixed with the polymer binder using known formulation technology. The nanoparticles form a suspension or colloidal mixture in the polymer in the liquid state. When the coating or ink is applied to the window substrate and cured to form a solid coating, the particles form a conductive path or circuit on the surface of the window, thereby providing the desirable shielding effects.

As used herein, the term “ink” or “conductive ink” refers to a liquid medium having at least the following components: a polymer, a conductive filler and a solvent, preferably an aqueous solvent. The ink can also include other components, such as lubricants, solubilizers, surfactants, suspension agents, dyes or pigments, anti-static additives, abrasion resistant additives, anti-glare additives, and the like. The terms “polymer”, “resin” and “binder” are frequently used interchangeably herein when referring to inks. However, the key feature of an ink is that it is typically formulated in an aqueous medium and can be readily applied to a surface to impart the desired EMI/RFI shielding properties to the printed surface. After application, the solvent is removed, i.e. by heating or evaporation at room temperature, leaving a stable conductive pattern on the resilient substrate. Water is typically used as the solvent of choice for inks, although other solvents such as butyl acetate and glycol esters can also be used. A suitable conductive ink for purposes of this invention is manufactured and sold by PChem Associates under the designation PF1200.

Curing of the coating or ink, once applied to the window, can be accomplished using conventional techniques, such as room temperature (evaporation), heat curing, ultraviolet (UV) radiation curing, chemical curing, electron beam (EB) or other curing mechanisms, such as anaerobic curing.

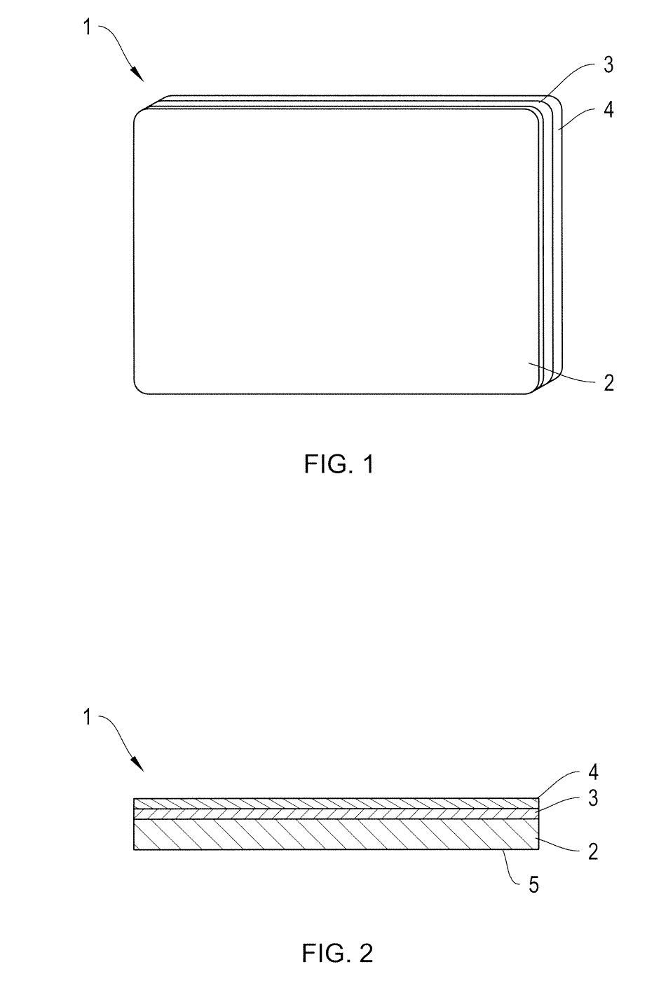

Referring now to FIG. 1, a shielded window 1 is shown in perspective view. The shielded window includes transparent substrate 2 having a patterned conductive ink coating 3 printed thereon. The pattern formed is the result of the printing process which applies the coating to the substrate. Window 2 is formed from a plastic (clear or tinted) or glass material. Optional plating layer 4 is shown applied over coating layer 3.

FIG. 2 is a cross-sectional view of the shielded window 1 of FIG. 1. As shown in FIG. 2, EMI shielding ink coating 3 is applied to the interior surface of substrate member 2. Ink layer 3 is typically less than about 10 microns in thickness. Plating layer 4 is applied to coating layer 3.

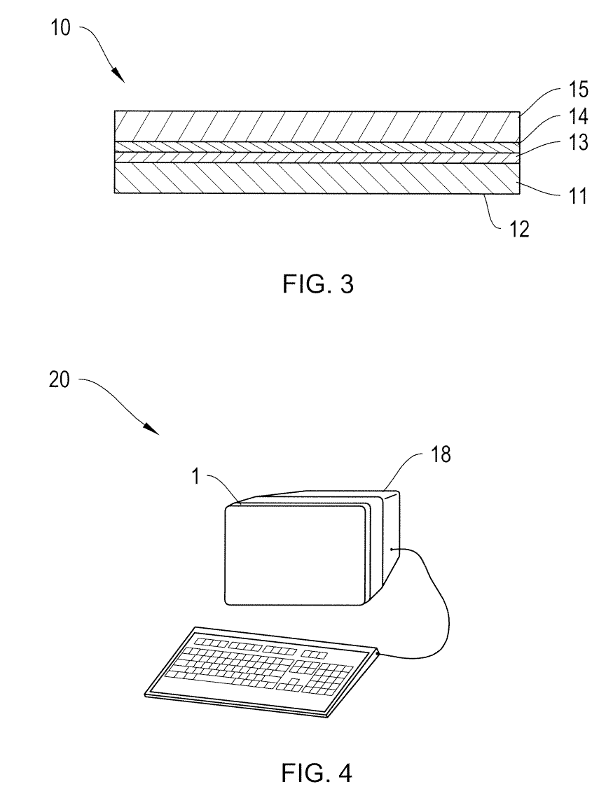

FIG. 3 is an alternative embodiment of window 1. Window 10 is assembled by coating transparent substrate 11 with conductive ink layer 13. Optionally, plated layer 14 is deposited onto ink layer 13, and a second transparent substrate 15 is applied over the ink/plating layers to form a sandwich with the other substrate 11.

FIG. 4 shows a typical piece of electronic equipment 20, in this case computer CRT console 18 incorporating a shielded window 1 according to the invention. The computer console 18 has a window 1 which is optically transparent for a viewer to observe, for instance, a video display or the graphical display of information or data.

The term “window”, as used herein, is intended to denote a display panel for an electronic or telecommunications device. Representative devices include instruments, displays (e.g. plasma displays), imaging equipment (e.g. magnetic resonance imaging equipment), computer equipment, monitors, telecommunications equipment (e.g. cellular phones), medical devices, and the like. The window substrate can be formed from a variety of materials including, but not limited to, glass or other glazing material (tempered, insulated, laminated, annealed or heat strengthened), and plastics (e.g. polycarbonates, polymethylmethacrylate, and the like).

The following examples illustrate the practical and unique features of the invention herein described. It should be understood that these examples should not be construed in any limiting sense.

### EXAMPLES

A conductive nanoparticle ink formulation was obtained from PChem Associates. The ink, designated as PF1200, is an aqueous formulation containing spherical silver nanoparticles having a nominal particle size of about 15 mm.

A window was coated with the ink in a square grid printed pattern having line widths in the range of from about 30 microns to about 100 microns and line spacings in the range of from about 300 microns to about 900 microns. The shielding results, compared to a baseline, were measured, and are shown in Table 1.

TABLE 1

| Frequency (MHz) | Attenuation (dB) |
|---|---|
| 30 | 18 |
| 40 | 22 |
| 60 | 27 |
| 80 | 34 |
| 100 | 32 |
| 200 | 46 |
| 400 | 49 |
| 600 | 47 |
| 800 | 40 |
| 1000 | 38 |
| 2000 | 35 |
| 4000 | 31 |
| 6000 | 29 |
| 8000 | 25 |
| 10000 | 30 |
| 12000 | 30 |
| 14000 | 28 |
| 16000 | 32 |
| 18000 | 30 |

Various other embodiments are possible and within the spirit and scope of the invention and the appended claims. The aforementioned embodiments are for explanatory purposes only, and are not intended to limit the invention in any manner. The invention intends to cover all the equivalent embodiments and is limited only by the appended claims. The pertinent disclosures of all patents listed herein are incorporated by reference in their entireties.

What is claimed is:

1. An EMI shielded window comprising:
a window substrate formed from a layer of a glass or plastic material, the window substrate having an outer and an inner surface; and
an optically transparent shielding layer applied to the interior or intermediate surface of the window substrate, the shielding layer comprising a filler of electrically-conductive and/or EMI absorptive nanoparticles.

2. The EMI shielded window of claim 1 wherein the window substrate plastic material is polycarbonate or polymethylmethacrylate.

3. The EMI shielded window of claim 1 wherein a metallic layer is plated onto the shielding layer, the metal being selected from the group consisting of copper, silver and nickel.

4. The EMI shielded window of claim 3 wherein the plated layer is treated in a sulfide both.

5. The EMI shielded window of claim 1 wherein the window is incorporated into an electronic device selected from the group consisting of CRT displays, flat panel monitors, cell phones, and computer monitors.

6. The EMI shielded window of claim 1 wherein the shielding layer has a thickness of 10 microns or less.

7. The EMI shielded window of claim 1 wherein the shielding layer comprises an admixture of a nanoparticle filler and a binder.

8. The EMI shielded window of claim 7 wherein the binder comprises a polymeric material such as a resin or an elastomer.

9. The EMI shielded window of claim 8 wherein the polymeric material is selected from the group consisting of acrylics, polyurethanes, epoxies, silicones, copolymers and blends thereof.

10. The EMI shielded window of claim 1 wherein the shielding layer is a conductive ink.

11. The EMI shielding layer of claim 10 wherein the conductive ink comprises conductive nanoparticles in an aqueous medium.

12. The nanoparticles of claim 1 which have maximum dimensions of less than about 100 nanometers.

13. The nanoparticles of claim 12 which have maximum dimensions of less than about 20 nanometers.

14. The nanoparticles of claim 1 which are selected from the group consisting of silver, gold, Monel, copper, steel, nickel, tin, ITO, and combinations thereof.
